(19) United States
(12) Patent Application Publication
(10) Pub. No.: US 2015/0030759 A1
(43) Pub. Date: Jan. 29, 2015

(54) MULTI-PLUME PULSED LASER DEPOSITION SYSTEM FOR HIGH-THROUGHPUT FABRICATION OF DIVERSE MATERIALS

(71) Applicant: Xiaojun Zhang, Fremont, CA (US)

(72) Inventor: Xiaojun Zhang, Fremont, CA (US)

(21) Appl. No.: 13/953,735

(22) Filed: Jul. 29, 2013

(51) Int. Cl. C23C 14/04; C23C 14/22; C23C 14/54

(52) U.S. Cl. CPC C23C 14/048; C23C 14/042; C23C 14/541; C23C 14/54; C23C 14/22
USPC 427/8; 427/596; 427/545; 427/557

(57) ABSTRACT

A multi-plume pulsed laser deposition (MPPLD) system has been provided for fabrication of an array of diverse materials in predefined regions on a substrate. In one embodiment, the method comprises splitting a high power laser beam into multiple laser beams, split laser beams being focused onto target materials, multiple plumes being generated on the surfaces of target materials, deposition of ablated target materials non-uniformly on a substrate covered with a mask, and heating the substrate during deposition.

### BACKGROUND OF THE INVENTION

1. Field of the Invention

Embodiments of the present invention generally relate to methods and apparatus for fabricating an array of diverse materials at known locations on a single substrate, which is essential in thin film fabrication of compounds.

2. Description of the Related Art

There has been tremendous interest in complex compound materials such as solar cell absorber materials (i.e. CuInₓGa₁₋ₓSe₂ (Repins, et al., Progress in Photovoltaics 16:235 (2008); Contreras, et al., Progress in Photovoltaics 7:311 (1999)) or CuIn₁₋ₓGaₓSe_{2-y}S_{y} (Ennaoui, et al., Solar Energy Materials and Solar Cells 67:31 (2001))) and high-temperature superconductive metal oxides (i.e. Ca(Fe₁₋ₓCoₓ)₂As₂ (Chuang, et al., Science 327:181 (2010)) or HgBa₂Caₘ₋₁CuₘO_{2m+2+δ} (Gao, et al., Physical Review B 50:4260 (1994))). Properties of these compounds are closely dependent on their compositions. In order to study and optimize the compounds, a series of materials with diverse compositions are usually grown one by one. This trial-and-error process is extremely time-consuming. It is therefore of great importance to find an efficient and systematic way to search through the compounds so that materials research, especially research on the ternary and quaternary materials that have not been well explored, can be greatly facilitated.

In 1995, Xiang et al. invented combinatorial approach method for making compounds, in which they used a series of masks while sputtering target materials (U.S. Pat. Nos. 5,985,356, 6,004,617, 6,326,090, 6,346,290, 7,442,665) (Xiang, et al., Science 268:1738 (1995); Wang, et al., Science 279:1712 (1998); Briceno, et al., Science 270:273 (1995)). The deposited film was separated by the masks into a library of segment samples on the substrate. Arrays containing different combinations, stoichiometries, and thickness were generated with a series of binary masks. More recently they revised the mask design to maximize the efficiency of library fabrication. A quaternary masking scheme was developed, which used a series of quaternary masks to subdivide the substrate into a series of self-similar patterns of quadrants, as shown in FIG. 1. Each mask was used up to four sequential depositions and each time the mask was rotated by 90 degrees. The precursors at each segment were mixed into one compound through post annealing process. Since amounts of deposited precursors were different at different segments, compositions of different segments on the substrate after annealing were different. A series of diverse compounds can thus be obtained in an efficient way. After fabricating these compound thin films at known locations on a substrate, it is possible to characterize the films by an automated scanning. Therefore both fabrication and characterization are greatly facilitated.

However, this combinatorial approach method that combines thin film deposition and physical masking techniques is a mixing-after-deposition process. It has problems associated with phase separation, mask misalignment, and complexity, etc. Those problems have not been solved yet and they have become fundamental issues of the technique.

Therefore, with the growing interest in complex compound materials, a reliable and efficient method for fabricating an array of diverse compound materials at known locations on a single substrate is essential.

Pulsed laser deposition (PLD) has been widely used in materials research since its successful growth of YBa₂Cu₃O_{7-δ} thin films for high temperature superconductor applications in 1987 (Dijkkamp, et al., Applied Physics Letters 51:619 (1987)). Compared with other techniques such as chemical vapor deposition and sputtering, pulsed laser deposition has its advantages. The composition of thin films deposited by pulsed laser deposition is almost the same as that of the target material. It is relatively easy for PLD to grow stoichiometric materials, which is very important for growth of compound materials, such as high temperature superconductive oxides and semiconductor compounds. In addition PLD is a very versatile technology. Most materials in the nature can be ablated by focused high energy UV laser. PLD can therefore be used to grow many kinds of materials, including metals, semiconductors, superconductors and insulators. The precursor material is just a small pellet, much easier to be obtained than sources of other techniques. With these advantages, PLD has been widely used in new materials research and exploration.

However, PLD is well-known to have a disadvantage, deposition rate non-uniformity issue. Film thickness deposited on substrates can be proximately described by cosⁿ (x) with a shape similar to a Gaussian curve (Tyunina, et al., Journal of Vacuum Science & Technology A 16:2381 (1998)). Growth rate of PLD films can decrease by more than 50 times at a distance of 60 mm from the center.

### SUMMARY OF THE INVENTION

Embodiments of the present invention generally relate to methods and apparatus for fabricating an array of diverse materials at known locations on a single substrate by a low-cost, high-throughput multi-plume pulsed laser deposition (MPPLD) system. The MPPLD comprises splitting a high-power laser beam into several spatially separate laser beams, which ablate several spatially separate targets and generate several spatially separate plumes, and depositing the materials through the spatially separate plumes on a substrate. With the high directionality and deposition rate non-uniformity of the spatially separate plumes, different locations on the substrate will have different ratios of materials coming from the spatially separate targets.

In one embodiment, the method comprises ablating spatially separate targets simultaneously. In another embodiment, the method comprises blocking split laser beams by a program-controlled laser block and thus ablating the spatially separate targets sequentially and programmably. In either embodiment, the method may further include introducing inert or reactive gas into the deposition chamber to control geometry of the plumes.

Various aspects of the present invention are further discussed in the detailed description below.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a series of quaternary masks used in combinatorial approach method of the prior art: Aᵢ, Bᵢ, Cᵢ, Dᵢ, and Eᵢ represent the five different masks designed.

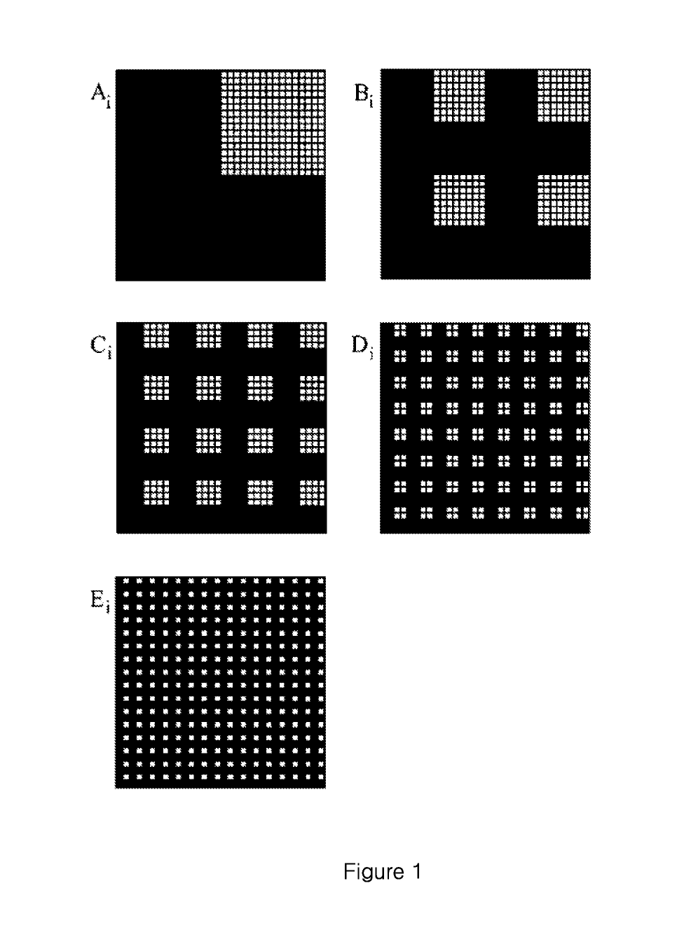

FIG. 2 illustrates schematically an exemplary design of the multi-plume pulsed laser deposition (MPPLD) system of the present invention in one embodiment.

FIG. 3 shows an exemplary mask design for multi-plume pulsed laser deposition (MPPLD) of the present invention in one embodiment.

FIG. 4 is an exemplary heater design for multi-plume pulsed laser deposition of the present invention in one embodiment.

FIGS. 5A and 5B illustrate target holders in one embodiment demonstrating different laser spot positions. FIG. 5A: spots are close; FIG. 5B: spots are far away. Rectangles represent focused laser spots.

To facilitate understanding, identical reference numbers have been used, where possible, to designate identical elements that are common to the figures. It is contemplated that elements and features of one embodiment may be beneficially incorporated in other embodiments without further recitation.

### DETAILED DESCRIPTION

Embodiments of the present invention generally provide various methods and apparatus for high-throughput fabrication of an array of diverse materials. While the following description details a system for high-throughput fabrication of an array of diverse materials and advantages of the system, the embodiments described herein should not be construed or limited to the illustrated examples, as the invention may admit to other equally effective embodiments.

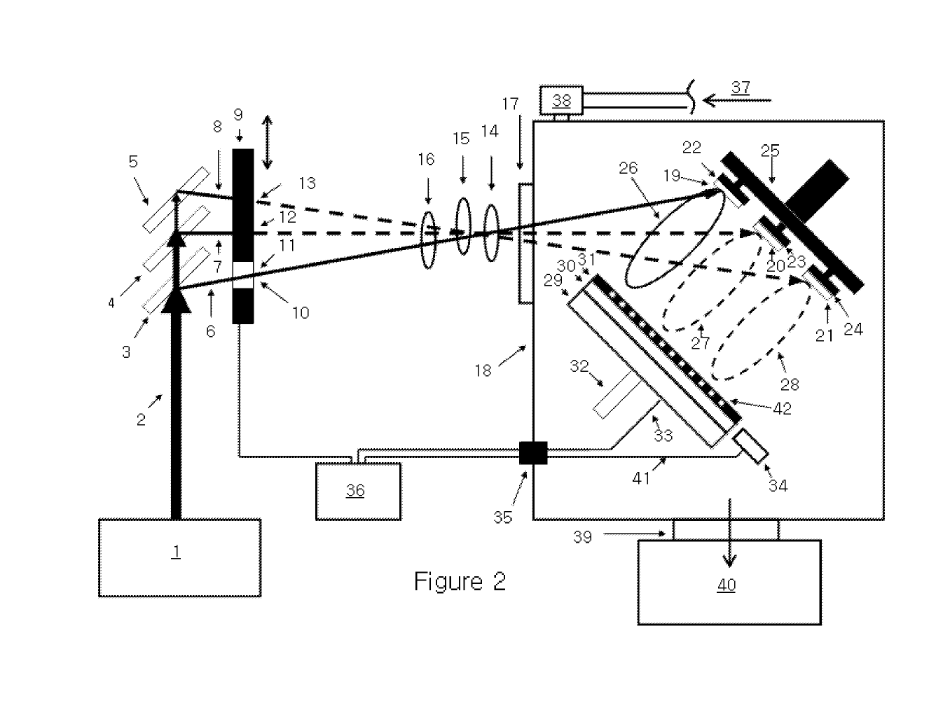

FIG. 2 illustrates an exemplary schematic design of the multi-plume pulsed laser deposition system of the present invention. An excimer laser 1 (i.e. Lambda Physik LPX 210i) produces a high energy UV laser beam 2 as shown in FIG. 2. Using two laser beam splitters 3, 4 (i.e. splitter 3: 30% reflectance and 70% transmittance; splitter 4: 50% reflectance and 50% transmittance) and one mirror 5, the laser beam is split into three laser beams 6, 7, 8. The beam splitters are mounted on optic mount flippers so that the setup is also compatible for two-plume deposition. A laser beam block 9 mounted on a stage and driven by a linear motor is used to sequentially let the beams 6, 7, 8 pass through. The laser block moves linearly on the stage with the hole 10 stopping sequentially at positions 11, 12, 13, 12, 11, 12, and so on. With the hole 10 at position 11 as shown in FIG. 2, beam 6 goes through the hole 10 of laser block 9, while beams 7 and 8 are blocked. Beam 7 will go through with the hole 10 at position 12; and beam 8 will go through with the hole 10 at position 13. In another embodiment, there is no laser block used so that all the laser beams can go through. Before entering vacuum chamber 18 through a quartz window 17, the three beams 6, 7, 8 are focused by spherical lenses 14, 15, 16, respectively. In some cases, the laser beams may share the same spherical lens. And the spherical lenses may have different focus length. Three targets 19, 20, 21 are mounted on target holders 22, 23, 24 and ablated by the focused lasers. The target holders 22, 23, 24 are mounted on a plate holder 25 and rotated by a motion feed-through HV-compatible motor. In FIG. 2, the targets are arranged triangularly. They may be arranged other ways to adjust the materials distribution. A substrate 30 (i.e. with a diameter of 4 inches or larger) heated by a resistance heater 29 and covered with a mask 31 is positioned facing the targets 19, 20, 21. An infrared heater may be used to replace the resistance heater 29. Plume 26 is generated on the surface of target 19 with the hole at position 11. Similarly plume 27 is generated with the hole at position 12, and plume 28 is generated with the hole at position 13.

A sensor (i.e. a crystal monitor) 34 is used for monitoring film thickness. Wires 33 and 41 from the heater 29 (including power supply and thermocouple) and the sensor 34 are connected outside through a HV-compatible electrical feed-through 35. A computer 36 is used to control the whole process, including motion of the laser block 9. A shaft 32 supporting the heater 29, the substrate 30, and the mask 31 is mounted on a HV-compatible linear motion feed-through and used to adjust target-to-substrate distance.

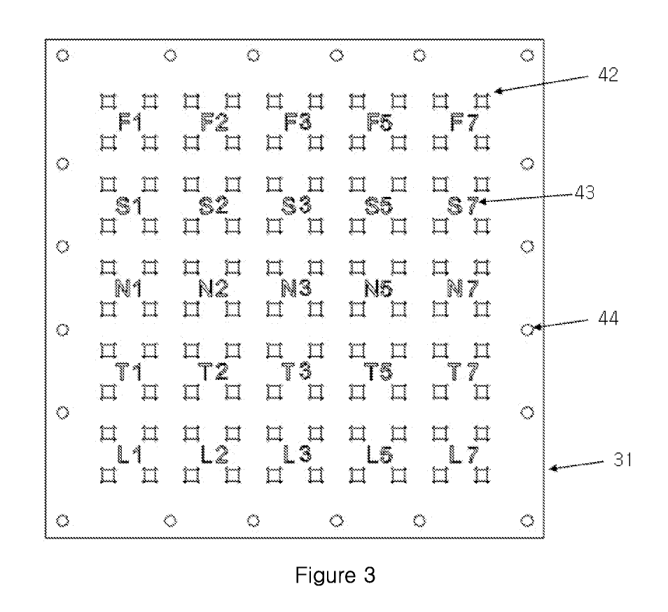

Gas 37 (inert gas or reactive gas such as oxygen) is introduced into the vacuum chamber 18 and controlled by a mass flow controller 38. Gas 37 is pumped out by a pump system 40. A valve 39 is installed between chamber 18 and pump 40 to provide another knob in addition to mass flow controller 38 to control process pressure, thus the plume shape. FIG. 3 shows an example of mask 31 used for multi-plume pulsed laser deposition. A stainless steel sheet is etched to generate 100 sample holes 42, labeling holes 43, and mounting screw holes 44. Thin mask (i.e. 0.1 mm thick) is used to minimize shadowing effect.

The high energy laser beam 2 is split into three individual beams 6, 7, 8, which are focused sequentially through spherical lenses 14, 15, 16, onto three targets (targets 19, 20, and 21). Target materials A, B, and C are ablated and deposited sequentially onto the substrate 30. The deposited species pass through holes 42 on mask 31 and form an array of separated films on the substrate 30 with the same shape of holes 42.

According to Anisimov et al.'s modeling, the normalized thickness can be expressed as (Tyunina, et al., Journal of Vacuum Science & Technology A 16:2381 (1998); Anisimov, et al., Applied Surface Science 96-98:24 (1996); Anisimov, et al., Journal of Experimental and Theoretical Physics 81:129 (1995)):

H(x,y)=(1+ax²+by²)^{-3/2} (1)

In the equation (1) above, H is the normalized thickness which equals to 1 at the plume center on the substrate; x and y are the distance to the plume center along x and y axes, respectively. And

$$a = \frac{{k}_{Ϛ}}{{Z}_{s}^{2}} , \\ b = \frac{{k}_{Ϛ}}{{k}_{η}^{2} {Z}_{s}^{2}} \qquad ( 2 )$$

Zₛ is the distance between the target and the substrate. k_{ζ} and k_{η} are values determined by characteristics of plume. They can be changed by adjusting ambient gas pressure, pulse energy of the laser, etc.

Deposition rate non-uniformity is usually a problem in thin film deposition, especially for applications where a large area of thin film with consistent and predictable properties is required. However, the present invention of multi-plume pulsed laser deposition (MPPLD) uses this property and makes it become an advantage for applications where fabricating an array of diverse materials at known locations on a single substrate is needed (i.e. high-throughput screening, optimization of new material composition, etc.).

From equation (1), it is seen that deposition rates at different locations are different because of their different distance to the plume centers. Therefore ratios of the different target materials and thus compositions of the segment films are different. Composition at a specific segment film is dependent on the plume characteristics (i.e. k_{ζ} and k_{η}), distance between plume centers, and distance between two neighboring segment film centers on the substrate, etc. Assuming the same molar volume and plume center deposition rate, it is expected to see three areas on the substrate, A-rich area, B-rich area, and C-rich area on the substrate near plume centers. Different distributions can be obtained by changing the parameters above.

Therefore, because of directionality of PLD plumes and deposition rate non-uniformity of pulsed laser deposition, this system is able to batch grow an array of thin films with different compositions on a single substrate.

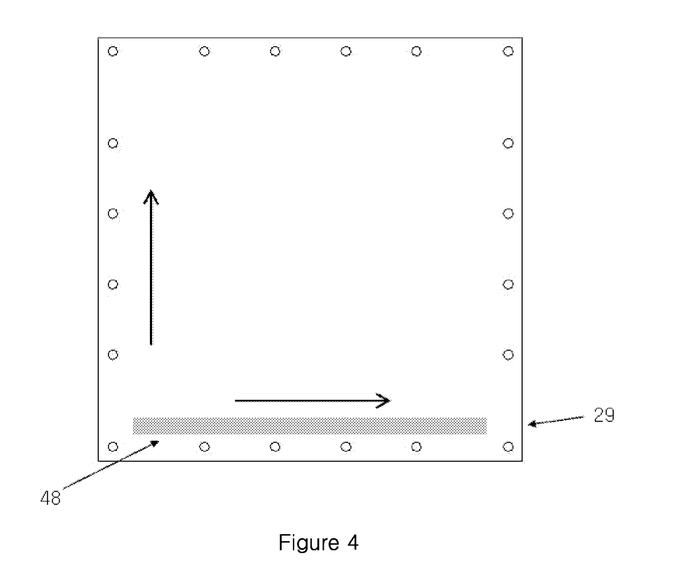

In one embodiment, substrate holder 29 is heated uniformly so that the samples are deposited at the same temperature and only have composition variation. This embodiment can be used for fine optimization of compound compositions. In another embodiment, a heater 48 may be attached (i.e. at the edge) to generate a gradient of temperature. As shown in FIG. 4, the samples will have composition variation in horizontal direction and temperature variation in vertical direction. This embodiment offers more varieties of the samples, which is good for fast screening of new materials.

The MPPLD system of the present invention has many advantages:

Just like combinatorial approach method, this system can fabricate compounds with different compositions together instead of one-by-one fabrication. It can be used to fabricate an array of 100 segment samples with different compositions easily within one or two days. Therefore efficiency of the thin film fabrication is dramatically increased.

With the ability to fabricate an array of thin films on a substrate, this technique can facilitate measurement process by replacing one-by-one measurement. By using a simple automatic scan or programmable switch circuits, the measurement can be automated and done much faster. For example, in order to fabricate one hundred solar cells on a substrate, electrodes can be deposited first using the same mask design mentioned above or lithography technology. Absorber materials with various compositions or doping are then grown using the MPPLD technique. After fabrication of an array of heterostructured solar cell devices on the substrate, it is then possible to measure them by mounting it onto a programmed motor stage or connecting electrodes on the substrate fabricated by reading/writing technologies widely used in microelectronic memory applications. By collecting output data automatically, it is possible to compare and optimize the composition, doping or temperature by an automatic program.

Instead of depositing precursor materials layer by layer and mixing them by post-deposition annealing, MPPLD mixes the precursor materials during deposition, which avoids the troublesome and problematic post annealing process in combinatorial approach method. Deposited films are therefore uniform in composition as long as deposition parameters are not changed during deposition. In combinatorial process, since precursor materials are deposited layer by layer, post annealing is necessary in order to ensure diffusion of precursor materials into a uniform mixture. However, this process has been proved to be problematic. It is often very difficult to find a suitable annealing temperature. If annealing temperature is too high, it is difficult to maintain film stoichiometry. If samples are annealed at a lower temperature, it then may need a very long time and also a complex process. In Xiang et al.'s previous work (Wang, et al., Science 279:1712 (1998)), a typical annealing was proceeded as follows: 200° C. for 150 hours, 400° C. for 24 hours, and 600° C. for 12 hours, followed by treatment at 1000° C. for 2 hours in a high-purity argon flow (with temperature ramping rates of 1° C. per minute). In addition, this annealing process is likely to get other phases of target materials. For example, for deposition of materials A, B, followed by material C, it is likely to get a stable phase only consisting of materials A and B (abbreviated as AB), or other phases such as BC, instead of a uniform mixture of A, B, and C.

It is much easier for this technique to deposit thick films. In order to deposit thick films, it only needs to run deposition for a longer time. Since combinatorial process needs post annealing to enhance diffusion and achieve uniform mixing, each layer of the precursor can not be too thick. Therefore combinatorial approach method needs more steps in fabricating thick films. For example, in order to deposit 1.5 μm thick film of ABC, it may need a series of steps, such as 30 nm layer A, 30 nm layer B, 30 nm layer C . . . . That requires frequent target change during deposition.

The MPPLD system of the present invention does not have mask misalignment problem since it uses just one mask. In combinatorial process, distribution of precursors is controlled by a series of masks. That method needs to change and align the masks during deposition. However, it is not easy to achieve those in a vacuum chamber with low cost. All those steps are currently performed mechanically, which inevitably include errors in alignment.

Composition change of segment samples fabricated by the MPPLD system of the present invention is ordered and continuous, which is good for measurement and fast screening. In order to save time and find promising samples quickly, measurement of all the samples therefore is not necessary. One sample can be picked out from every four or nine neighbored samples. Detailed measurement can be done after promising properties have been found.

Process involved in multi-plume pulsed laser deposition of the present invention is simple and the cost is low. It does not need to change masks or targets during deposition. It is also much easier for this technique to heat the substrate. In-situ heating is essential for fabrication of many thin film materials. However, in combinatorial process, the mechanical alignment of masks has been shown to be very difficult while heating the substrate. In addition, for combinatorial process, in-situ heating may cause lower-order phases such as previously mentioned AB or BC phase, which, if they are stable, are often difficult to be removed in post annealing.

This MPPLD technique of the present invention is flexible. By changing only one mask, size of each segment sample, total number of samples, or distribution of the samples, or even size of the substrate can be changed easily. However, in combinatorial process, since it uses a series of masks and these masks are critically mounted on a stage, change of masks and segment sample size is difficult.

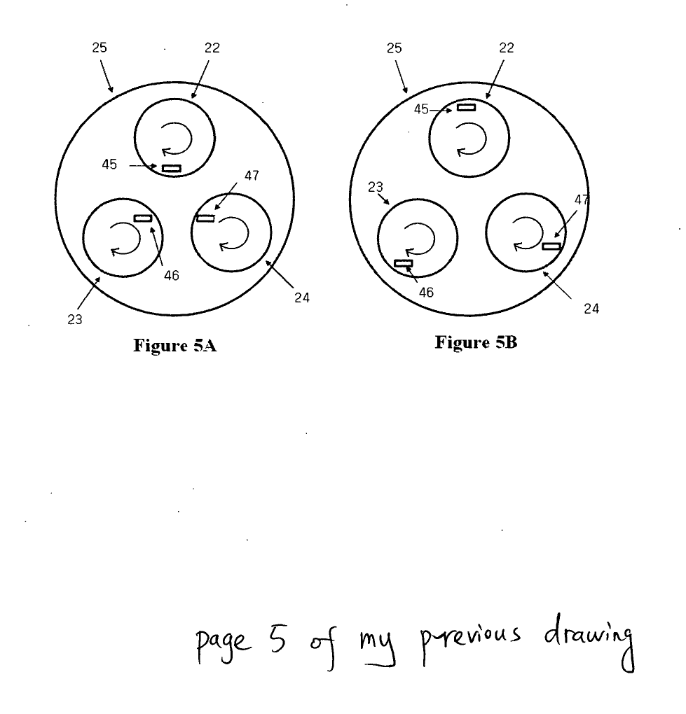

For various experimental purposes, distribution of target materials on the substrate in multi-plume pulsed laser deposition (MPPLD) of the present invention is easy to be changed by controlling the process. Sharp composition change might sometimes be needed for fast screening. Sometimes small variation might be needed for detailed characterization. The precursor distribution can be easily changed by adjusting substrate-to-target distance, ambient gas pressure, and even distance between the plumes. More gradual change of compositions is expected at a larger substrate-to-target distance (Tyunina, et al., Journal of Vacuum Science & Technology A 16:2381 (1998)). The distribution can also be changed by adjusting ambient gas pressure during deposition. In addition, as shown in FIGS. 5A and 5B, it is also easy to change the distance between laser spots 45, 46, 47 by adjusting beam splitters 3, 4 and mirror 5. Laser spot positions on the targets can be changed, and as a result positions of the plumes can be changed, which obviously will affect precursor distribution on the substrate.

In summary, a low-cost, high-throughput multi-plume pulsed laser deposition (MPPLD) system has been provided and compared to previous technique in detail. With plume directionality and deposition rate non-uniformity of pulsed laser deposition, this new system has advantages such as low cost, high throughput, simplicity, flexibility, etc. and is suitable for high-throughput fabrication of an array of diverse compound materials at known locations on a single substrate, which is essential in compound materials research and fabrication.

While the foregoing is directed to embodiments of the present invention, other and further embodiments of the invention may be devised without departing from the basic scope thereof, and the scope thereof is determined by the claims that follow.

1. A method of making an array of diverse materials, comprising:
splitting said high power laser beam into said multiple laser beams;
said split laser beams being focused by said spherical lenses onto said target materials in said vacuum chamber;
said multiple plumes being generated on the surfaces of said target materials;
deposition of ablated said target materials non-uniformly on said substrate covered with said mask; and
said heater heating said substrate during said deposition.

2. The method of claim 1, further including mounting said laser splitters on optic mount flippers to be compatible with deposition with a different number of plumes.

3. The method of claim 1, wherein said target materials are solid materials spaced from each other mounted on target holders.

4. The method of claim 1, further including a program-controlled laser block to sequentially pass said split laser beams.

5. The method of claim 1, wherein said heater is a resistive heater.

6. The method of claim 1, wherein said heater is an infrared heater.

7. The method of claim 1, wherein said heating includes uniform heating of said substrate.

8. The method of claim 1, wherein said heating includes non-uniform heating of said substrate to generate a temperature gradient.

9. The method of claim 1, wherein said vacuum chamber is an enclosure having an optical window to allow said focused split laser beams to pass therethrough.

10. The method of claim 1, further including a translation unit to adjust the distance between said substrate and said targets.

11. The method of claim 1, further including introduction of said gas into said vacuum chamber to adjust said plume geometry.

12. The method of claim 4, further including a system to program control said laser block, said heating of said substrate, and collect feedback from said sensor.

13. The method of claim 1, wherein said mask is a temperature-resistant sheet with an array of said holes.
